(19) United States
(12) Patent Application Publication
(10) Pub. No.: US 2012/0181677 A1
(43) Pub. Date: Jul. 19, 2012

(54) SEMICONDUCTOR DEVICE PACKAGE WITH TWO COMPONENT LEAD FRAME

(75) Inventors: Anthony C. Tsui, Saratoga, CA (US); Hongbo Yang, Shanghai (CN); Ming Zhou, JiaDing (CN); Weibing Chu, Shanghai (CN); Anthony Chia, Singapore (SG)

(73) Assignee: GEM Services, Inc., Santa Clara, CA (US)

(21) Appl. No.: 13/348,298

(22) Filed: Jan. 11, 2012

Related U.S. Application Data
(63) Continuation-in-part of application No. 12/903,626, filed on Oct. 13, 2010, now Pat. No. 8,106,493.
Application No. 12/903,626 is a continuation-in-part of application No. 12/186,342, filed on Aug. 5, 2008.
(60) Provisional application No. 61/053,561, filed on May 15, 2008.
(60) Provisional application No. 61/042,602, filed on Apr. 4, 2008.

(51) Int. Cl. H01L 23/495; H01L 23/34

(52) U.S. Cl. 257/675; 257/706; 257/E23.08; 257/E23.051

(57) ABSTRACT

Embodiments of the present invention relate to the use of stamping to form features on a lead frame of a semiconductor device package. In one embodiment, portions of the lead frame such as pins are moved out of the horizontal plane of a diepad by stamping. In certain embodiments, indentations or a complex cross-sectional profile, such as chamfered, may be imparted to portions of the pins and/or diepad by stamping. The complexity offered by such a stamped cross-sectional profile serves to enhance mechanical interlocking of the lead frame within the plastic molding of the package body. Other techniques such as selective electroplating and/or formation of a brown oxide guard band to limit spreading of adhesive material during die attach, may be employed alone or in combination to facilitate fabrication of a package having such stamped features.

### CROSS-REFERENCE TO RELATED APPLICATION

This application is a continuation-in-part of U.S. patent application Ser. No. 12/186,342, filed Aug. 5, 2008, by Tsui et al., which claims priority to U.S. Provisional Patent Application No. 61/053,561, filed May 15, 2008, both of which are incorporated by reference in their entirety herein for all purposes.

This application is also a continuation-in-part of U.S. patent application Ser. No. 12/903,626, filed Oct. 13, 2010, by Tsui et al., which is a division of U.S. patent application Ser. No. 12/191,527, filed Aug. 14, 2008, which issued as U.S. Pat. No. 7,838,339 on Nov. 23, 2010, which claims priority to U.S. Provisional Application No. 61/042,602 filed Apr. 4, 2008, all of which are incorporated by reference in their entirety herein for all purposes.

### BACKGROUND OF THE INVENTION

FIGS. 1A-1H show simplified cross-sectional views of a conventional process for fabricating a package for a semiconductor device. The views of FIGS. 1A-H are simplified in that the relative proportions of the various components are not shown to the scale.

In FIG. 1A, a planar, continuous rolls 102 of conducting material such as copper, is provided.

In FIG. 1B, material is removed from regions of the planar roll 102 utilizing a chemical etching process. This chemical etching process involves forming a mask, and then etching in regions exposed by the mask, followed by removal of the mask. This chemical etching serves to define a central diepad 104 surrounded by a metal matrix 106. Although not shown in the particular cross-sectional view in FIG. 1B, portions of the diepad 104 may remain integral with the metal matrix 106.

FIG. 1C shows partial etching of the backside of portions of the patterned roll 102. Etched regions 104a of the periphery of the diepad 104 will later serve to allow the diepad to be physically secured within the plastic molding of the package body. Etched regions 108a correspond to portions of pins of the lead frame. These etched regions 108a will later serve to allow the pins to be physically secured within the plastic molding of the package body. FIG. 1C marks the step of completion of formation of lead frame 103.

FIG. 1D shows the formation of an electrically conducting adhesive material 110 on the die attach region 104b of the diepad 104. This electrically conducting adhesive material maybe comprise soft solder deposited in molten form. Alternatively, the electrically conducting adhesive material may comprise solder paste that is deposited in the form of small-sized particles of solder in a binder such as a solvent.

FIG. 1E shows the die-attach step, wherein the back side 112a of semiconductor die 112 is placed against electrically conducting adhesive material 110. As shown in FIG. 1E, one consequence of this die attach step may be the spreading of material 110 on the diepad 104 beyond the perimeter of the die 112.

FIG. 1F shows a subsequent step, wherein bond wires 114 are attached between contacts on the top surface 112b of the die 112 and pins 108.

FIG. 1G shows a further subsequent step, wherein the diepad 104, die 112, bond wires 114, and portions of the pins 108 are encapsulated with a plastic molding material 116 to define a body 118 of the package. As previously indicated, the recesses 104a and 108a serve to physically secure the diepad and pins, respectively, within the package during this encapsulation step.

FIG. 1H shows a subsequent singulation step, wherein the package 120 is separated from the surrounding metal frame by a sawing process.

While the conventional process flow just described is adequate to form a semiconductor device package, it may offer certain drawbacks. In particular, the partial etching step shown in FIG. 1C may be difficult to achieve, and hence adds to the cost of manufacturing the device. In particular, this partial etching step involves a number of steps, including the highly accurate patterning of a mask, followed by only partial etching in exposed areas and then removal of the mask. In particular, the partial etching of the metal roll may be difficult to halt with sufficient accuracy and repeatability.

Accordingly, there is a need in the art for a process for forming a semiconductor device package which avoids the need for a partial etching step.

### BRIEF SUMMARY OF THE INVENTION

Embodiments of the present invention relate to the use of stamping to form features on a lead frame of a semiconductor device package. In one embodiment, portions of the lead frame such as pins are moved out of the horizontal plane of a diepad by stamping. In certain embodiments, a complex cross-sectional profile, such as chamfered, may be imparted to portions of the pins and/or diepad by stamping. The complexity offered by such a stamped cross-sectional profile serves to enhance mechanical interlocking of the lead frame within the plastic molding of the package body. Other techniques such as selective electroplating and/or formation of a brown oxide guard band to limit spreading of adhesive material during die attach, may be employed alone or in combination to facilitate fabrication of a package having such stamped features.

These and other embodiments of the present invention, as well as its features and some potential advantages are described in more detail in conjunction with the text below and attached figures.

### BRIEF DESCRIPTION OF THE DRAWINGS

FIGS. 1A-H show simplified cross-sectional views of a conventional process for fabricating a package.

FIGS. 2A-2K show simplified cross-sectional views of an embodiment of a process in accordance with the present invention for forming a package.

FIGS. 2CA-2CC show end views of various complex cross-sectional profiles that may be imparted by stamping according to embodiments of the present invention.

FIG. 3 shows a simplified view of the flow of a process according to an embodiment of the present invention.

FIG. 4A shows a simplified perspective view of the lead frame of an embodiment of a package in accordance with the present invention housing three die.

FIG. 4B is a simplified plan view showing the die and bond structures of the package of FIG. 4A.

FIG. 5 is a simplified plan view showing a lead frame according to another embodiment of the present invention.

FIG. 5A is a simplified cross-sectional view taken along the line A-A′ of FIG. 5.

FIG. 5B is a simplified plan view showing positioning of a die and bond wires on the lead frame of FIG. 5.

FIG. 6 is a simplified plan view showing a lead frame according to yet another embodiment of the present invention.

FIG. 6A is a simplified cross-sectional view taken along the line A-A′ of FIG. 6.

FIG. 7A is a simplified cross-sectional view of another embodiment of a lead frame of the present invention.

FIG. 7B shows an enlarged plan view of a portion of the lead frame of FIG. 7A.

FIG. 7C shows an enlarged cross-sectional view of the lead frame of FIG. 7B taken along line C-C′.

FIG. 8 shows a simplified plan view of a package in accordance with an embodiment of the present invention.

FIG. 8A shows a simplified cross-sectional view taken along line 8A-8A′, of the package embodiment of FIG. 8.

FIG. 8B shows a simplified cross-sectional view of an alternative embodiment of a package in accordance with the present invention.

FIG. 8C shows a simplified cross-sectional view of another alternative embodiment of a package in accordance with the present invention.

FIG. 8D shows a simplified cross-sectional view of yet another alternative embodiment of a package in accordance with the present invention.

FIG. 8DA shows a simplified cross-sectional view of still another alternative embodiment of a package in accordance with the present invention.

FIGS. 8E-EA show plan and cross-sectional views, respectively, of an embodiment of a lead frame in accordance with an embodiment of the present invention.

FIGS. 8FA-FB show plan and cross-sectional views, respectively, of an alternative embodiment of a lead frame in accordance with an embodiment of the present invention.

FIGS. 8GA-GB show plan and cross-sectional views, respectively, of an alternative embodiment of a lead frame in accordance with an embodiment of the present invention.

FIG. 8H shows a simplified plan view of an embodiment of a lead frame in accordance with the present invention.

FIGS. 8IA-IB show plan and cross-sectional views, respectively, of an alternative embodiment of a lead frame in accordance with an embodiment of the present invention.

FIG. 8J shows a simplified plan view of an embodiment of a lead frame in accordance with the present invention.

FIG. 8K shows a simplified plan view of an embodiment of a lead frame in accordance with the present invention.

FIGS. 8LA-LB show plan and cross-sectional views, respectively, of an alternative embodiment of a lead frame in accordance with an embodiment of the present invention.

FIG. 8M shows a simplified plan view of an embodiment of a lead frame in accordance with the present invention.

FIG. 8N shows a simplified plan view of an embodiment of a lead frame in accordance with the present invention.

FIG. 8O shows a simplified plan view of an embodiment of a lead frame in accordance with the present invention.

FIG. 9A shows a simplified plan view of the upper metal layer of an alternative embodiment of a lead frame in accordance with the present invention, that is configured to support multiple die.

FIG. 9B shows a simplified plan view of the lower metal layer of an alternative embodiment of a lead frame in accordance with the present invention, that is configured to support multiple die.

FIG. 9C shows a simplified cross-sectional view of an embodiment of a package in accordance with the present invention that is configured to house multiple die.

FIG. 10 shows a simplified plan view of an arrangement of multiple die in a lead frame according to an embodiment of the present invention.

FIG. 11 shows a simplified cross-sectional view of an embodiment of a package in accordance with the present invention featuring multiple die in a stacked configuration.

FIG. 12 shows a simplified cross-sectional view of an alternative embodiment of a package in accordance with the present invention.

FIG. 13 shows a simplified cross-sectional view of an alternative embodiment of a package in accordance with the present invention.

FIG. 14 is side view of a device with a two component lead frame according to embodiments of the invention.

FIGS. 15A and 15B show a top view of a device with a two component lead frame according to embodiments of the invention.

FIG. 16 is a flowchart of a process for forming a two component lead frame according to some embodiments of the invention

### DETAILED DESCRIPTION OF THE INVENTION

Embodiments of the present invention relate to the formation of semiconductor device packages utilizing stamping. In one embodiment, portions of the lead frame such as pins are moved out of the horizontal plane of a diepad by stamping. In certain embodiments, the pins of a package may be imbued with a chamfered or other complex cross-sectional profile by a stamping process. Other techniques, employed alone or in combination, may facilitate fabrication of a package by stamping.

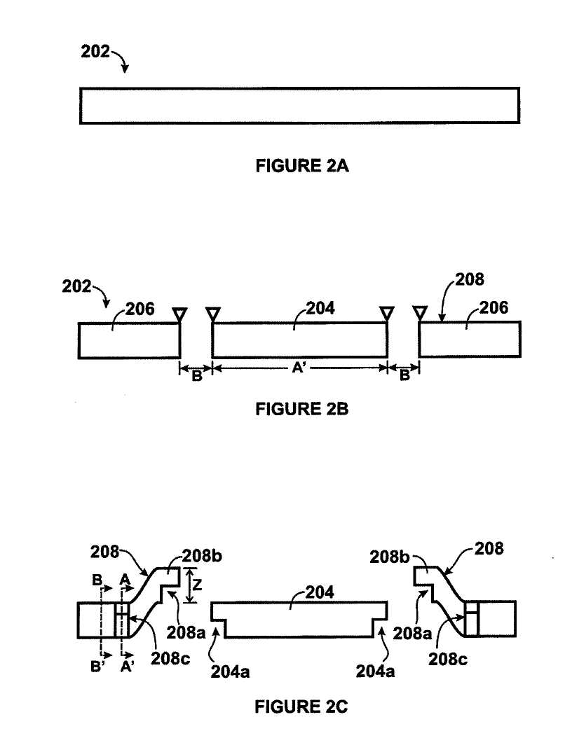

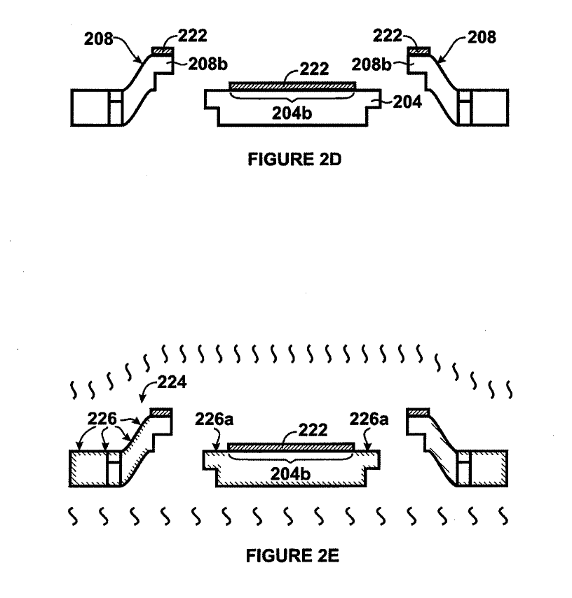

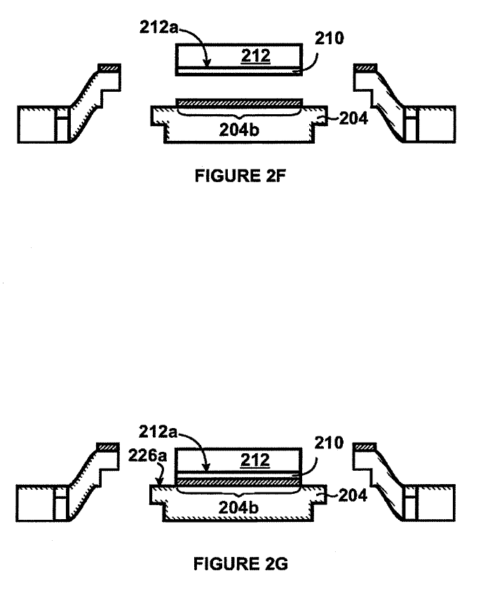

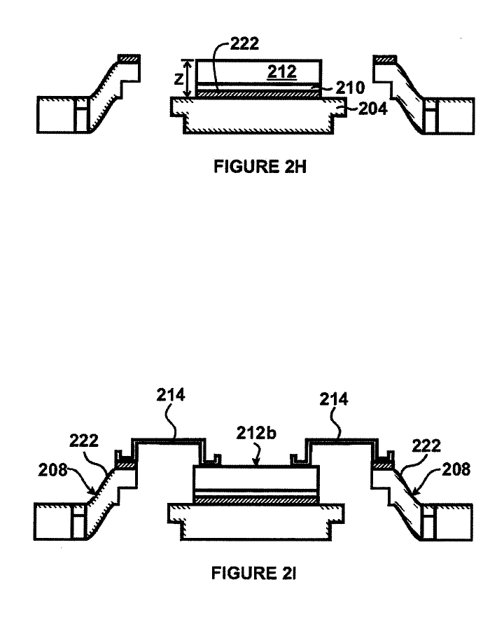

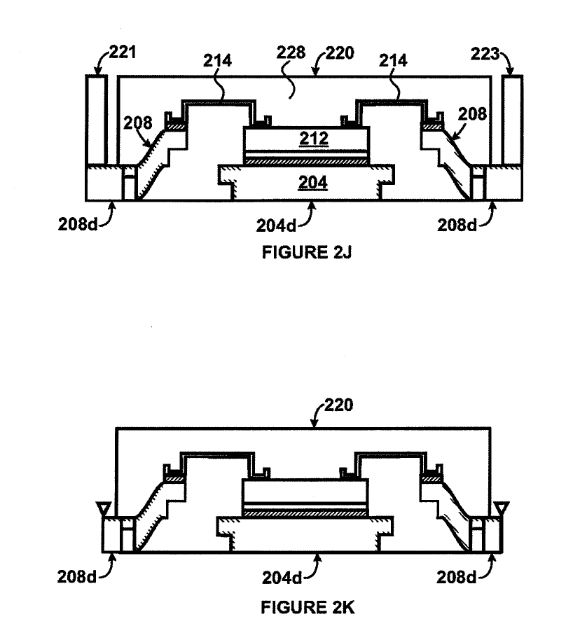

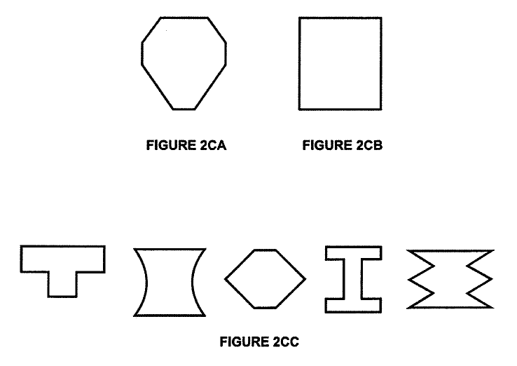

FIGS. 2A-2K show simplified cross-sectional views of a process in accordance with an embodiment of the present invention for forming a semiconductor device package. The views of FIGS. 2A-2K are simplified in that the relative proportions of the components of the package are not shown to scale.

In FIG. 2A, a planar, continuous roll 202 of conducting material such as copper, is provided. In particular embodiments, the metal roll may have a thickness of between about 4-20 mils (0.004″-0.020″). In certain embodiments, the metal roll has a thickness of between about 6-10 mils (0.006″-0.010″).

In FIG. 2B, material is removed from the planar roll 202 utilizing a punching process, with points of removal of material indicated by the triangles. This punching process serves to define a central diepad 204 surrounded by a metal matrix 206. Although not shown in the particular cross-sectional view in FIG. 2B, portions of the diepad 204 may remain integral with the surrounding metal matrix 206.

Also defined during the punching step of FIG. 2B are a plurality of pins 208 integral with the surrounding metal matrix. According to certain embodiments, the minimum width of these pins is about 0.15 mm, and the minimum pitch between the pins is about 0.4 mm, where the pitch is defined as the distance between the center lines of adjacent pins. In particular embodiments where the thickness of the metal roll is between about 6-10 mils, the width of these pins is about 0.25 mm and the pitch between the pins is about 0.5 mm.

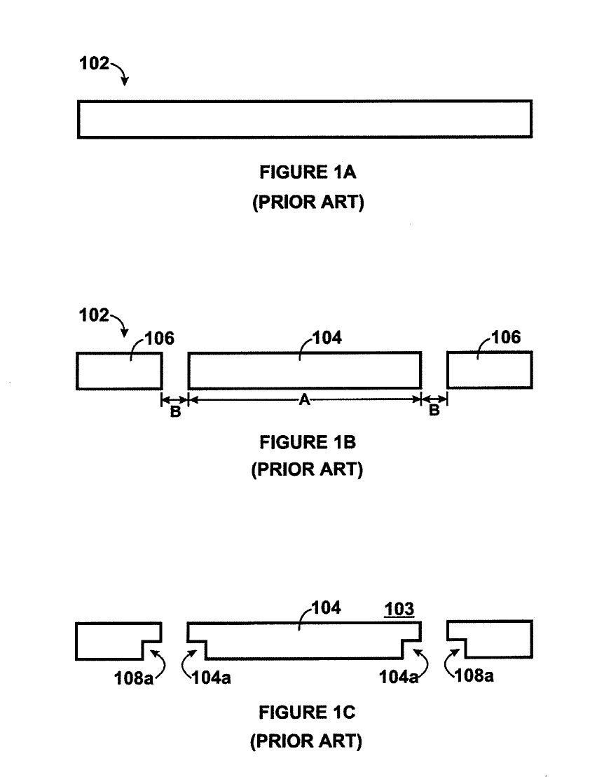

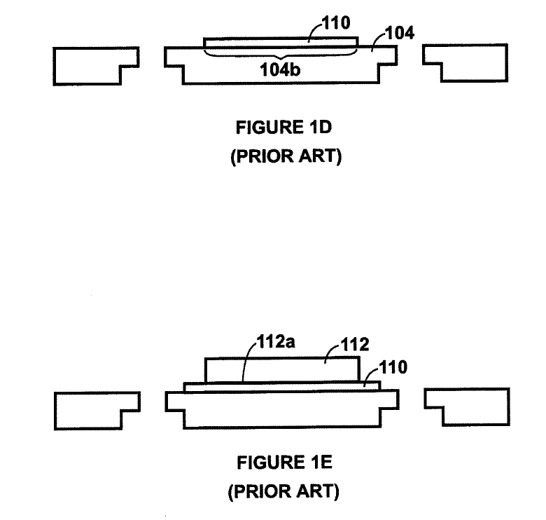

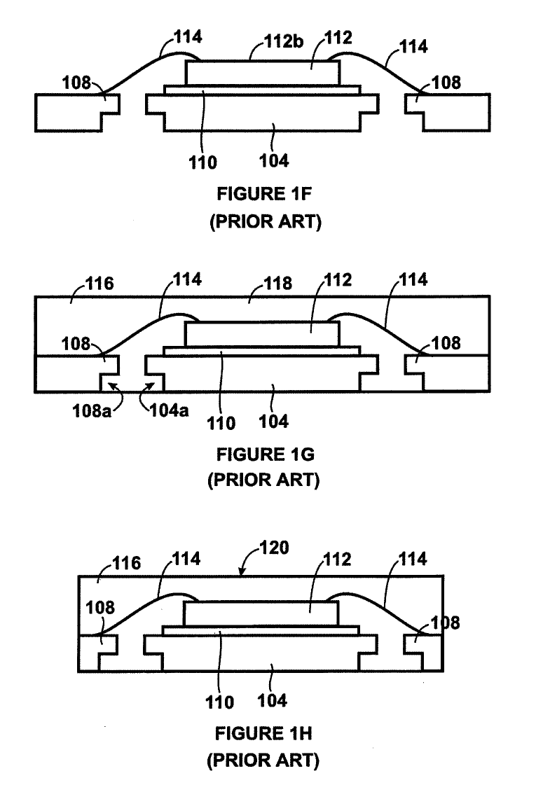

FIG. 2B shows that the lateral dimension (A′) of the diepad 204, may be slightly smaller than the corresponding lateral dimension (A) of the diepad 104 formed by the conventional process shown in FIG. 1B. As discussed in detail below, this smaller diepad size may be a result of fabrication of the package utilizing stamping techniques.

Specifically, FIG. 2C shows the use of stamping to impart several features to the lead frame. One feature formed by stamping is an indentation at the edge of the diepad and/or pins. Specifically, FIG. 2C shows indentation 204a around the periphery of the underside of diepad 204. FIG. 2C also shows indentation 208a at the edge of the pin. proximate to the diepad. By receiving the plastic molding of the package body during the subsequent encapsulation step, stamped indentations 204a and 208a serve to enhance mechanical interlocking between the body of the package and the diepad and pins respectively.

Another lead frame feature shown in FIG. 2C formed by stamping, is elevation of a portion 208b of pins 208 above a horizontal plane of the diepad 204. This raising of portions 208b of the pins 208 closest to the diepad 204, causes the pins to penetrate deeper into the body of the package, helping to physically secure the pins within the encapsulating plastic mold of the package body. Raising of the pin portions also relieves stress in the bond structure, by making the ends of the bond structure located at approximately the same height.

According to certain embodiments, the stamping process may raise the pin portions 208a to a height Z above the surface of the diepad 204, where Z corresponds approximately to an expected thickness of a die supported on the diepad, and a conducting adhesive material between the die and the diepad.

Still another feature which may be imparted to a lead frame during the stamping of FIG. 2C, is a complex cross-sectional profile to a middle portion 208c of the pin 208. Specifically, FIG. 2CA shows a view of middle portion 208b of the pin 208, taken along section A-A′ of FIG. 2C. FIG. 2CB shows a view of a portion of the pin 208 taken g section B-B of FIG. 2C.

In the particular embodiment of FIGS. 2CA-CB, the middle pin portion 208b exhibits a chamfered profile, with sides positioned at an angle relative to the vertical disposition of the sides of the other portions of the pin. In this embodiment, the complex cross-sectional profiles imparted to the lead frame by stamping according to embodiments of the present invention, enhances mechanical interlocking of the pins within the plastic body of the package. In addition, the stamped cross-sections allow the pins to offer a larger surface area to the surrounding molding material, thereby further enhancing mechanical interlocking between lead frame and package body. Moreover, the complex stamped cross-sectional profiles may allow the pins to better relieve physical stress during the subsequent singulation step, thus avoiding damage at the interface between the pin and the plastic package body.

While FIG. 2CA shows the complex cross-sectional profile as being a chamfer, this is not required by the present invention. In other embodiments, the cross-sectional profile imparted by stamping could be hour-glass shaped, T-shaped, H-shaped, angled or curved concave or convex, or saw tooth shaped, as shown in FIG. 2CC.

The various features formed by stamping in FIG. 2C need not be created in a single stamping step. One or more separate stamping impacts under different conditions could be employed to create the stamped features.

FIG. 2D shows a simplified view of a post-stamping electroplating process according to an embodiment of the present invention. Specifically, electroplated material 222 is selectively formed on certain regions of the lead frame.

Specifically, electroplated material 222 may be formed on the die attach portion 204b of the diepad 204 that is expected to receive the die. Where the die to be supported by the diepad has an electrical contact on its lower surface (such as the drain of a MOSFET), the electroplated material 222 will likely contain silver (Ag).

Another location of electroplated material is at an end of the elevated portion 208a of the pin 208 proximate to the diepad 204. As discussed in detail below, these electroplated regions are expected to receive the electrically conducting bond wire, bond ribbon, or bond clip from the top surface of the supported die.

The composition of the electroplated material 222 may be dictated by the composition of the bond wire/ribbon/clip with which the electroplated material will be in contact. The following TABLE provides a listing of electroplated materials under different conditions.

TABLE

| Bonding | Material | Finished Lead Surface for Bonding |
|---|---|---|
| Wire | Gold Wire | Ni, Ag, Ni/Au, or Ni/Pd/Au |
| | Al-Wire | Bare Cu, Ni, Ag, Ni/Au, or Ni/Pd/Au |
| | Cu-wire | Bare Cu, Ni, Ni/Au, or Ni/Pd/Au |
| Ribbon | Al | Bare Cu, Ni, Ag, Ni/Au, or Ni/Pd/Au |
| | Cu— | Bare Cu, Ni, Ni/Au, or Ni/Pd/Au |
| Clip | Cu | Bare Cu, Ni, Ni/Au, or Ni/Pd/Au |

FIG. 2E shows a next step in the process, wherein the electroplated lead frame is exposed to an oxidizing ambient 224. As a result of this exposure, portions of the lead frame that have not been electroplated, become oxidized and form “brown oxide” 226. As discussed below, this brown oxide 226 may exhibit properties that are useful in subsequent steps in the package. In particular, formation of a brown oxide guard band 226a circumscribing the die attach area 204b, may be useful.

FIG. 2F shows the next step, wherein die 212 is provided having its lower surface 212a already coated with an electrically conducting adhesive material 210 such as soft solder. This step obviates the need for the selective deposition of the electrically conducting adhesive material on the die attach area that is shown in FIG. 1D of the convention process.

FIG. 2G shows the next step, wherein die 212 bearing electrically conducting adhesive material 210, is placed against die attach area 204a of diepad 204. In this step, the presence of the brown oxide guard band 226, secures to restrain the flow of the soft solder material beyond the confines of the die attach area. Specifically, the roughness and non-wetting properties of the brown oxide inhibit the spreading of the soft solder.

During the package singulation process shown in FIG. 2K, the pins 208 are exposed to significant physical strain as the punching blade moves through the metal. However, during this slicing process the angled edges offered by the chamfered cross-sectional profile of the pin shown in FIG. 2CA, serves to enhance mechanical interlocking of the pins within the plastic body material, and reduce physical strain at the interface between the pins and the package body.

The package singulation process in FIG. 2K leaves package 220 having exposed surface 208d of pin portions 208 and exposed surface 204d of diepad 204 stripped of brown oxide and ready for soldering to an underlying printed circuit (PC) board (not shown).

While the particular embodiment shown above depicts fabrication of a package housing a single die, the present invention is not limited to such a package. Alternative embodiments in accordance with the present invention could be used to form packages housing two, three, or even larger numbers of die.

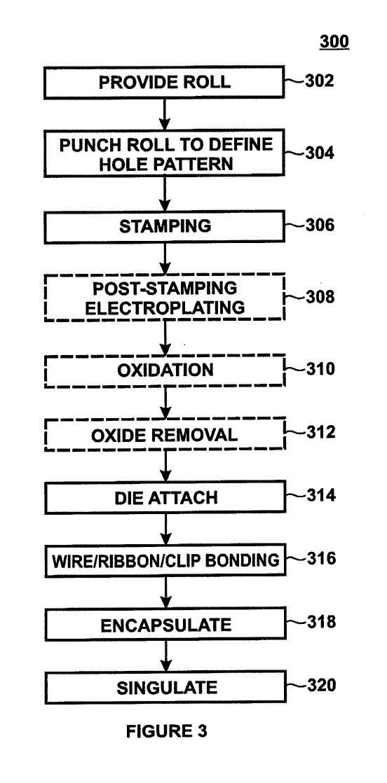

FIG. 3 shows a simplified flow diagram of a process for fabricating a package according to an embodiment of the present invention. In a first step 302 of process 300, a continuous planar roll of conducting material is provided.

In a second step 304 of process 300, holes are punched completely through to remove material from the metal role and thereby define the pattern of the diepad and pins.

In a third step 306, the patterned metal roll is subjected to one or more stamping processes to create features on the pin and diepad portions of the package. As discussed in detail above, examples of such features include indentations on the underside of the diepad, pin portions exhibiting a chamfered cross-sectional profile, and raised pin portions.

In a fourth step 308, portions of the lead frame may optionally be electroplated with an appropriate metal. Examples of such electroplated regions include the die attach area, and the raised portions of the pins that are expected to receive an end of a bond structure such as a wire, ribbon, or clip having its other end in contact with the die.

In a fifth step 310, the stamped lead frame is exposed to an oxidizing ambient. A result of this exposure to the oxidizing ambient is the formation of brown oxide on all exposed portions of the lead frame surface. As discussed previously, this oxidation may desirably lead to the formation of an oxide guard band circumscribing the die attach area.

In a sixth step 312, brown oxide on the bottom surface of the pins and diepad may be removed. In certain embodiments, this oxide removal may be accomplished by physically lapping the bottom of the lead frame. In other embodiments, this oxide removal may be accomplished by exposure to a chemical etching environment.

The oxide removal step may occur immediately following the oxidation step, as indicated in FIG. 3. In other embodiments, however, the oxide removal step may occur later in the process, for example following the encapsulation step.

In a seventh step 314, the die is attached to the die attach area. In certain embodiments, this die attach step may include prior application of an electrically conducting adhesive material to the die attach area of the diepad. Alternative embodiments may utilize a die having its back side already coated with the electrically conducting adhesive material.

In an eighth step 316, the appropriate bonding structure(s) are attached between the surface of the die and the appropriate pin, which may be electroplated. As discussed above, the bond structure may be a conducting clip, wire, or ribbon.

In a ninth step 318, the die, bond structure, and portions of the pins and diepad are encapsulated within a plastic molding material to form the body of the package. During this step, the diepad and pins remain fixed to the surrounding metal matrix of the original metal roll.

In a tenth step 320, the individual package is singulated from the surrounding metal matrix by punching through the metal. During this singulation process, a chamfered or other complex cross-sectional profile imparted to the pins by stamping, may enhance mechanical interlocking of the pins within the package body, and allow the pins to relieve physical stress resulting from the shearing of the metal.

In additional steps (not shown), the package may be attached to an underlying PC board utilizing solder. The previous removal of brown oxide by lapping may facilitate the performance of this step.

The process described above represents only one particular embodiment of the present invention. Other embodiments may omit certain steps, include additional steps, or perform the steps in a specific order other than that indicated.

For example, the selective electroplating step is not required, and according to certain embodiments the bonding structure may be in contact with the bare metal of the roll rather than an electroplated feature. Moreover, the use of a bonding clip is not required by the present invention and certain embodiments could employ only bonding ribbons or wires to establish electrical connection with contact(s) on the top of the die.

Embodiments in accordance with the present invention offer a number of possible advantages over conventional package fabrication processes. In particular, by avoiding the need for complex and difficult-to-achieve steps of forming raised/recessed features on the lead frame by marking and partial etching, embodiments in accordance with the present invention offer cost savings.

Comparison of FIGS. 1B and 2B indicates that one characteristic that may not be offered by embodiments of the present invention, is a larger diepad area available to support a larger die. Specifically, features on the lead frame are formed by stamping that does not completely remove the material of the metal roll. Thus, in order to maintain the same lateral spacing B between the diepad and pins as in the etched package, embodiments of the present invention may utilize a diepad having slightly reduced dimensions (A′ vs. A) in order to accommodate the stamped metal.

However, various other aspects of processes according to embodiments of the present invention may serve to offset any smaller size of the diepad and die. For example, the formation of the brown oxide guard band circumscribing the die attach area, effectively constrains the flow of the electrically conducting adhesive material during the die attach process. This in turn allows reduction in the peripheral area of the diepad that must be allocated to avoid the flowed material from undesirably affecting regions outside the die attach area.

Moreover, certain embodiments involve the use of clips instead of bond wires. Such use of a bond clip may allow for a reduced resistance electrical connection between the die contacts and the surrounding pins. This may in turn permit the use of a smaller die having performance comparable to a larger one.

Similarly, the use of selective electroplating may also offer a reduced resistance electrical connection between the die contacts and the surrounding pins. Again, this offers the possibility of a smaller die exhibiting performance comparable to a larger die.

The above figures present an exemplary embodiment only, and the present invention is not limited by this particular embodiment. For example, while the above figures show a diepad having indented features formed by stamping, this is not required by the present invention. According to other embodiments, a diepad could have raised features formed by stamping, such as raised features on a periphery of the diepad.

Moreover, while the specific embodiment shown above includes pin portions proximate to the diepad that are elevated by stamping, the present invention is not limited to this approach. In accordance with alternative embodiments, portions of the pins distal from the diepad could be inclined downward by stamping, thereby offering an embodiment wherein the bottom of the diepad is not exposed following encapsulation of the package body.

In addition, while the above figures describe an embodiment of a package configured to house a single die, this is not required by the present invention. Alternative embodiments of packages according to the present invention can be configured to house two or more die.

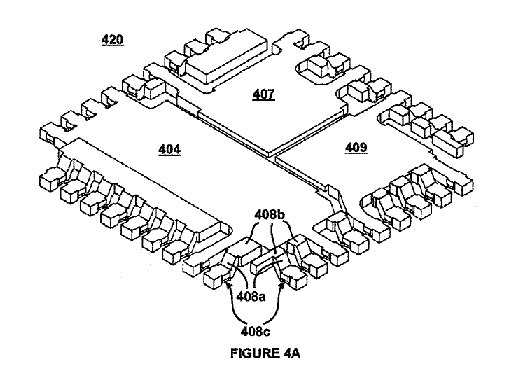

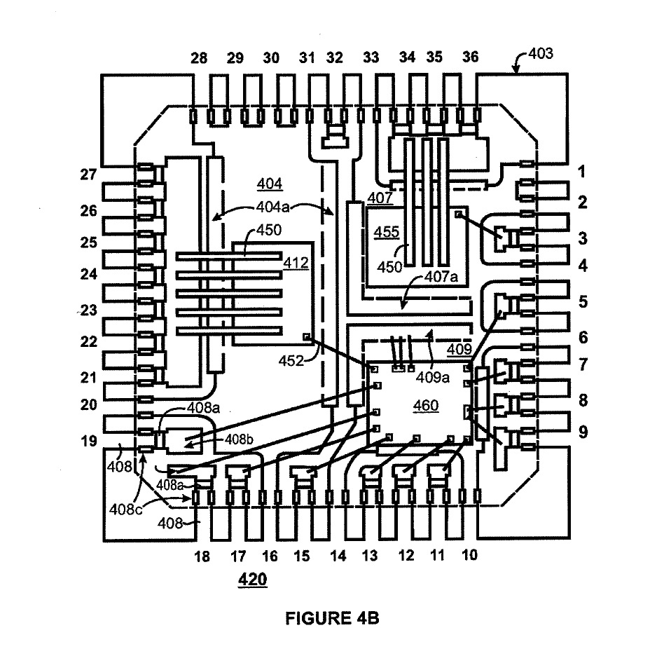

For example, FIGS. 4A-B show different views of an embodiment of a quad flat no-lead (QFN) package housing three different die. Specifically, FIG. 4A shows a perspective view of the lead frame 403 only of the QFN package. FIG. 4B shows a plan view of the entire package 420 of FIG. 4A, including the die housed therein and the bonding structures attached thereto, with the outline of the plastic package body shown.

The lead frame 403 of the particular embodiment of FIGS. 4A-4B is formed from a copper roll having a thickness of between about 6-10 mils. The pins 408 have a width of about 0.25 mm or greater. The pitch between the pins is about 0.5 mm or greater.

Specifically, the stamped end frame 403 of package 420 comprises three diepads 404, 407, and 409, respectively supporting first MOSFET die 412, second MOSFET die 455, and integrated circuit (IC) die 460. Diepad 404 is the largest of the three, having an elongated die attach area 404a configured to support MOSFET die 412.

The pins of the package offer contact with three discrete portions of the first MOSFET die 412. Specifically, ganged pin nos. 21-27 are in low resistance communication with the source contact located on the top surface of the die 412, through clips 450. Pins 16, 20, and 28-31 are integral with the diepad 404, and hence offer a low resistance electrical communication with the drain of the MOSFET through a contact in the bottom surface of the die. The gate of the MOSFET is in electrical communication with a contact of the integrated circuit (IC) die 409 through bond wire 452.

Similarly, the pins of the package 420 offer contact with three discrete portions of the second MOSFET die 455. Specifically, ganged pin nos. 34-36 are in low resistance communication with the source contact located on the top surface of the die 455, through bonding clips 450. Pins 1-2, 4, and 33 are integral with the diepad 407, and hence offer a low resistance electrical communication with the drain of the MOSFET through a contact in the bottom surface of the die. The gate of the MOSFET is in electrical communication with pin 3 through bond wire 452.

Unlike the MOSFET die just described, the IC die 460 features a large number of contacts on its top surface. These various contacts are in electrical communication with the following pin nos.: 5, 7-9, 11-13, 15, and 17-18.

IC die 460 may or may not have an electrical contact in its lower surface. If it does, pins 6, 10, and 14 integral with the diepad 409 provide for low electrical resistance communication with that underside contact.

The multi-die embodiment of the QFN package 420 of FIGS. 4A-4B includes the stamped features of the single die package. Specifically, the diepads include indentations 404a, 407a, and 409a respectively as shown in dashed lines. These indentations are formed by stamping, and help to provide mechanical interlocking of the diepads with the encapsulant of the plastic mold material.

Another feature of the multi-die embodiment of the QFN package 420 of FIGS. 4A-4B is the chamfered cross-sectional profile 408c of portions of the pins 408 lying just inside the plastic package body. As described above, these chamfered cross-sectional profiles serves to enhance mechanical interlocking with the surrounding molding of the package body, and increase the amount of surface area of the pin in contact with the plastic molding. In addition, the angled orientation of the sides of the pins serves to reduce stress within the package during punching at the time of singulation.

Yet another feature of the multi-die embodiment of the QFN package 420 of FIGS. 4A-4B is the raising of portions of the pins above the horizontal plane of the diepad. Specifically, during fabrication portions of the pins are bent by stamping to impart them with an inclined portion 408a and a corresponding raised portion 408b proximate to the diepads. As previously indicated, such a profile helps to ensure that the pins remain securely embedded within the plastic molding of the package. The raised pin profile also serves to ease strain in the bonding structure, by placing the surface of the pin at the height of the top surface of the die expected to be supported by the diepad.

As previously indicated, the multi-die embodiment of the QFN package 420 includes an IC die which may or may not have an electrical contact on its back side. Such an IC die would not be expected to generate as much heat as other dies such as MOSFETs. Accordingly, an epoxy die attach film may be used to adhere the IC die to the diepad. Such an epoxy film may be formed as a solid, and would not be expected to flow or spread during the die attach step. Accordingly, for embodiments of the present invention where a package is fabricated housing only an IC die, formation of a brown oxide guard band followed by lapping, may not be necessary.

While the embodiments described above illustrate the use of stamping to impart a chamfered cross-sectional profile to pin portions, this particular cross-sectional profile is not required by embodiments of the present invention. According to alternative embodiments, stamping could imbue pins with other cross-sectional profiles and remain with the scope of the invention. Examples of such other cross-sectional profiles include but are not limited to hourglass shaped, angled or curved concave, angled or curved convex, or saw tooth.

During conventional package fabrication processes, the diepad may be secured to the surrounding metal of the roll utilizing tie-bar structures. These conventional tie-bar structures stabilize the diepad during die attach, and encapsulation steps, and are then severed during the package singulation.

One advantage of embodiments in accordance with the present invention, is the dispensing of the need for a tie-bar structure. Specifically, the embodiment of FIGS. 4A-B does not include tie-bars or severed portions thereof. In particular, prior to the singulation step, each diepad is connected to a surrounding metal frame by way of at least two non-integral pins that would be integral with surrounding portions of the metal matrix. These integral pin portions function in the role of a tie-bar, physically stabilizing the diepad and insuring the physical integrity of the lead frame prior to the singulation step.

The absence of tie-bars offer a number of advantages. One advantage is having more area in the corners of a package to place more pins. Another advantage is that there is no exposed part of tie bars on a surface of a package.

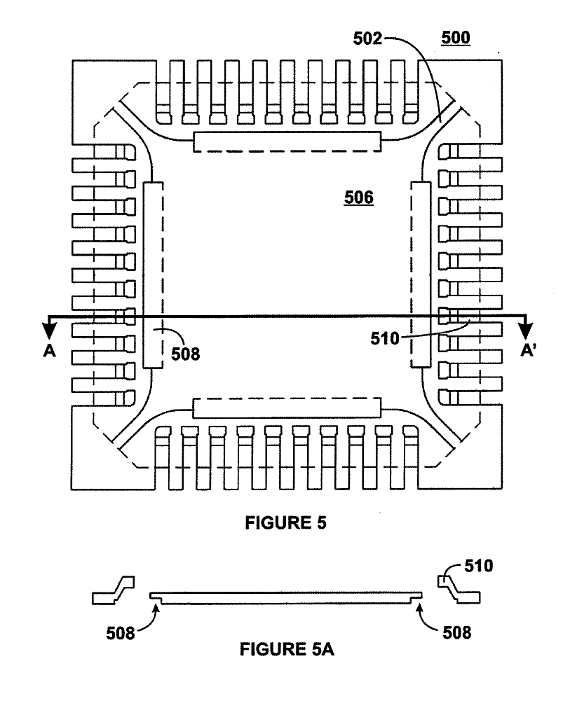

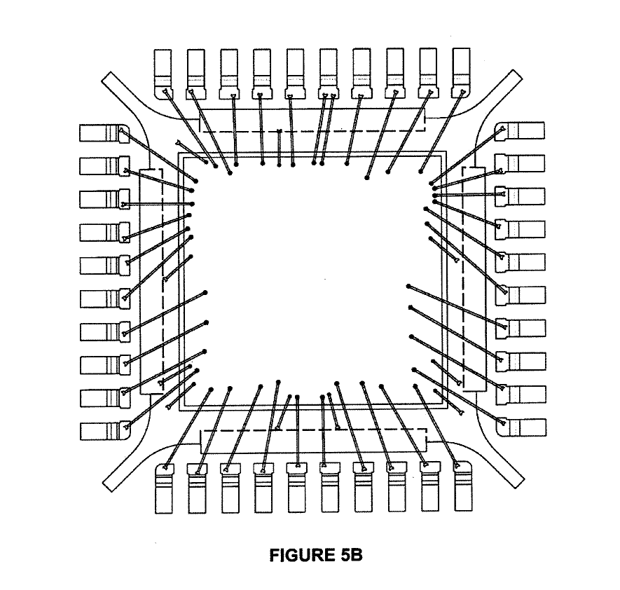

While the embodiment of FIG. 4B shows a lead frame lacking tie-bars and including ganged groups of non-integral pins for communicating with non-IC die, this is not required by the present invention. FIG. 5 is a simplified plan view showing a lead frame according to another embodiment of the present invention, and FIG. 5A is a simplified cross-sectional view taken along the line A-A′ of FIG. 5.

The embodiment of FIGS. 5-5A shows a lead frame 500 having tie-bars 502 integral at the corners of the diepad 506. Coined indents 508 located on the underside of the diepad 506 are configured to interlock with plastic molding of the package upon encapsulation.

FIG. 5B is a simplified plan view showing positioning of a die and bond wires on the lead frame of FIG. 5. As shown in FIG. 5B, the large number of exclusively single individual pins 510 of this embodiment, are suitable for communicating through bond wires with the plurality of contacts present on a top surface of a complex IC die such as a microprocessor, that is supported on the diepad.

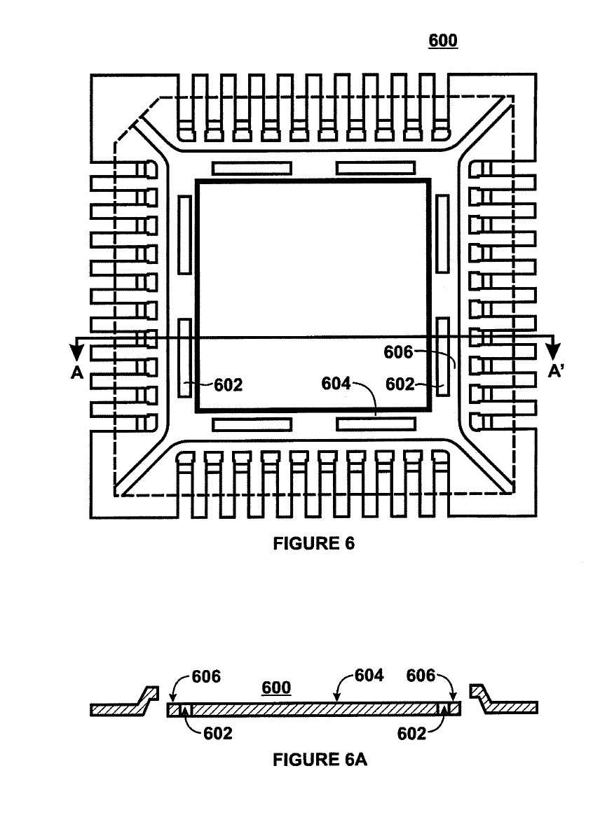

Types of features other than those explicitly described above, can be formed on a lead frame by coining according to alternative embodiments of the present invention. For example, FIG. 6 is a simplified plan view showing a lead frame according to yet another embodiment of the present invention, supporting a die. FIG. 6A is a simplified cross-sectional view taken along the line A-A′ of FIG. 6, absent the die.

The embodiment of FIGS. 6-6A shows a lead frame 600 which includes a number of holes 602 formed by stamping or coining, in the periphery of the diepad region 604. The holes 602 allow penetration of plastic molding during the encapsulation step, thereby providing additional mechanical interlocking of the lead frame.

In addition, the holes 602 serve to isolate and preserve rim/runway area 606 (from the die to the edge of the die-pad) for down bonding. In particular the presence of the holes serves to contain unwanted bleeding or overflow of die attach material during the die attach step. For example, in one embodiment where the diepad has an overall width of 5.1 mm, the hole may have a width of 0.2 mm, and may be separated from the diepad edge by a distance of 0.2 mm forming the down bond runway.

Lead frames according to embodiments of the present invention may combine multiple features that are formed by coining. For example, the lead frame shown in FIGS. 6A-B features both the coined holes, and pins having elevated portions and cross-sectional profiles formed by coining.

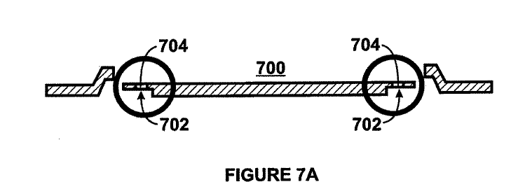

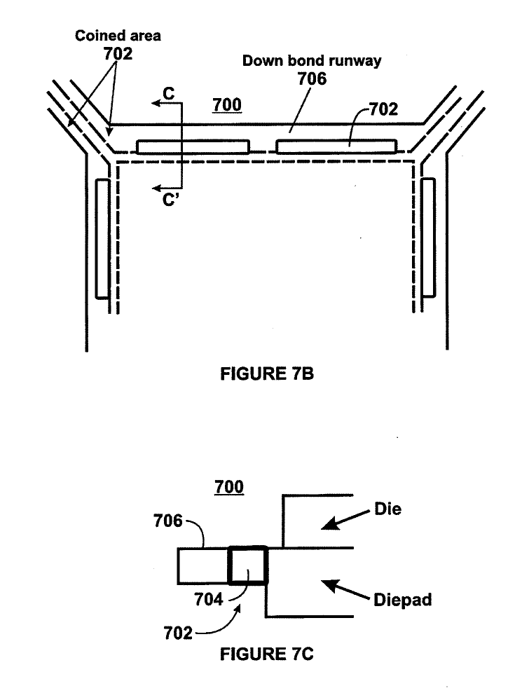

As a further example of a lead frame having multiple coined features, FIG. 7A is a simplified cross-sectional view of another embodiment of a lead frame of the present invention. FIG. 7B shows an enlarged plan view of a portion of the lead frame of FIG. 7A including a supported die. FIG. 7C shows an enlarged cross-sectional view of the lead frame of FIG. 7B taken along line C-C′, including a supported die.

Specifically, the lead frame 700 of the embodiments of FIGS. 7A-C includes both a coined indent 702 on the underside of the periphery of the diepad, and a plurality of holes 704 formed by coining in the periphery of the diepad region. The location of holes 704 define a down bond runway region 706 that is configured to receive a down bond wire from the supported die, and which is shielded from overflow of die attach material by the holes.

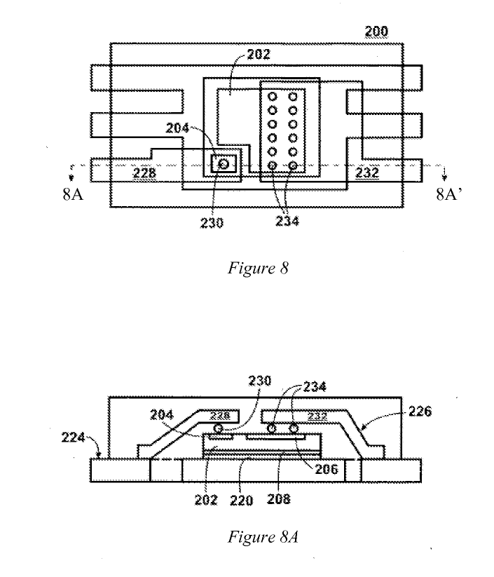

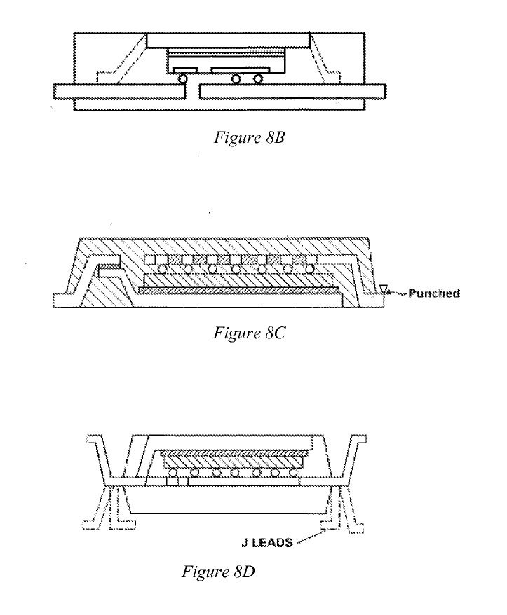

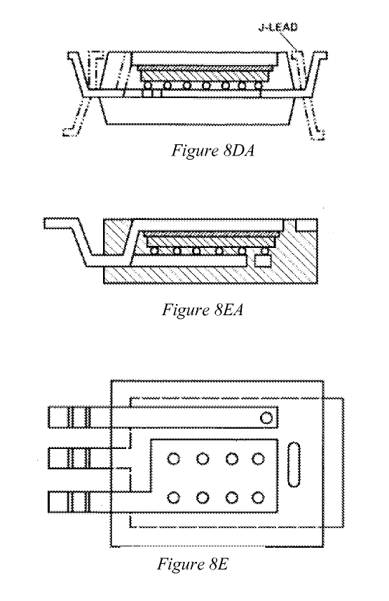

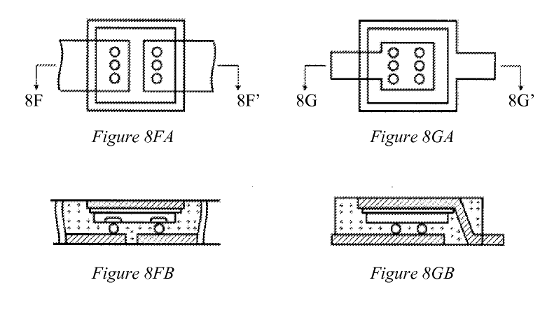

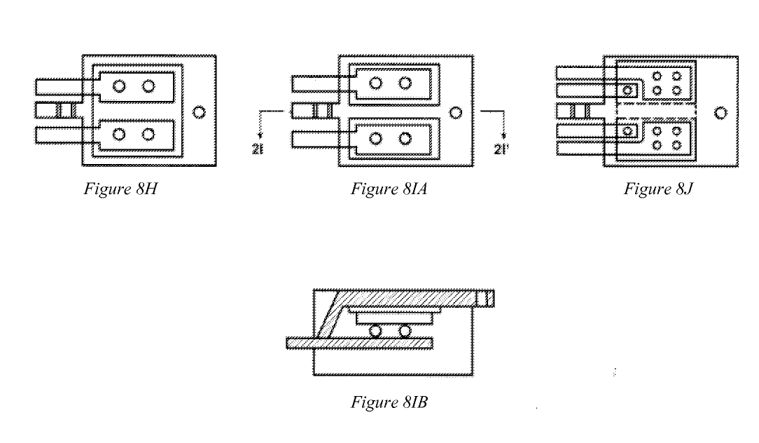

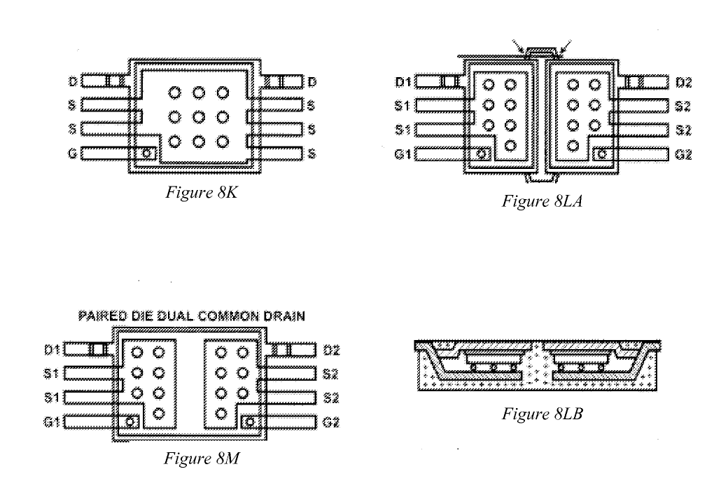

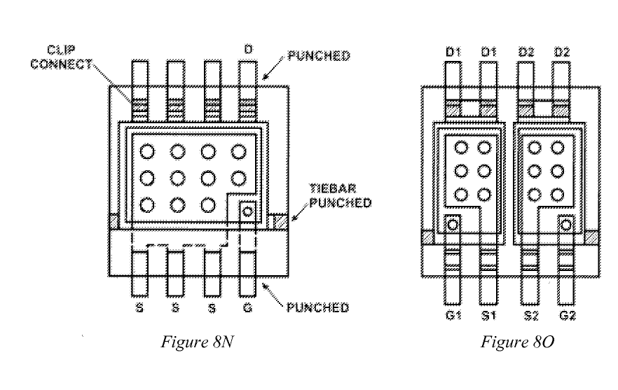

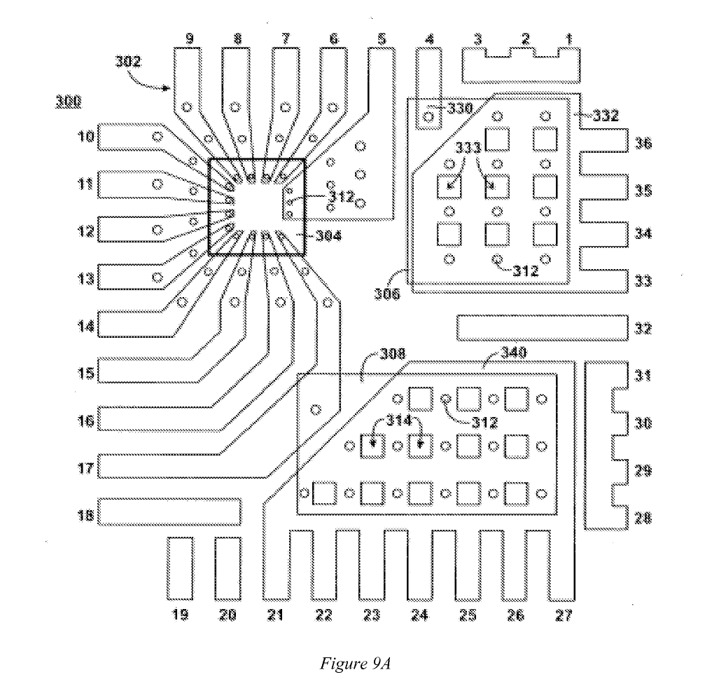

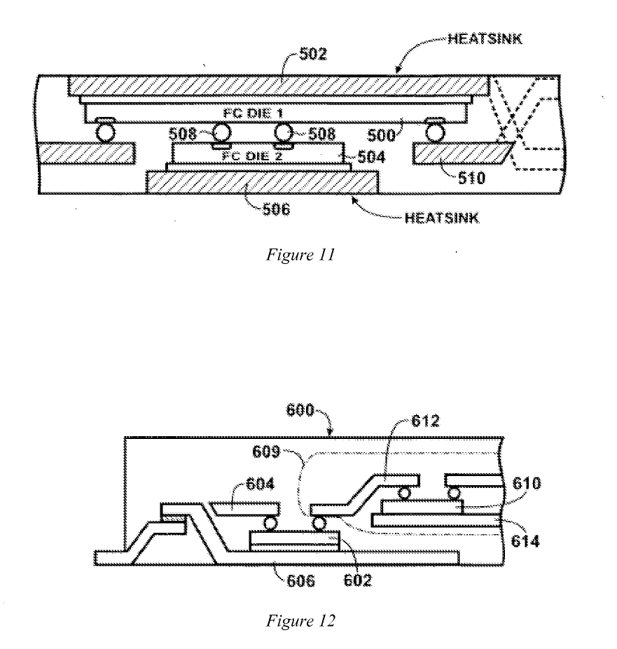

The following disclosure describes drawings that may include callouts that are the same as other callouts in the previous drawings. In such situations the callouts refer to drawings in FIGS. 8-13.

FIG. 8 is a simplified plan view of an embodiment of a package in accordance with the present invention. FIG. 8A is a simplified cross-sectional view of the package of FIG. 8, taken along the cross-sectional line 8A-8A′.

Package 200 comprises MOSFET die 202 having a top surface featuring gate pad 204 and source pad 206. The bottom surface of MOSFET die 202 features a drain contact 208.

Drain contact 208 is in electrical communication with an underlying first metal layer 224, through electrically and thermally conducting adhesive material 220. One example of such an electrically and thermally conducting material is solder. In certain embodiments, the first metal layer can be provided pre-bumped with solder balls or pre-formed with a solderable contact surface.

Integral projections of the first metal layer 224 extend outside of the plastic package body to provide leads for electrical contact with the MOSFET drain. The underside portion of the first metal layer that is exposed by the package body, may serve as a heat sink.

Package 200 includes a second metal layer 226 overlying the die. A first portion of 228 of the second metal layer is in electrical communication with gate pad 204 through a solder connection 230. A second portion 232 of the second metal layer is in electrical communication with source pad 206 through multiple solder connections 234. Portions 228 and 232 of the upper metal layer 226 are in turn routed to extend out of the plastic package body to serve as leads for connection to the gate and source. This routing may involve changing the vertical height of the metal portions 228 and 232 to match the height of the first metal layer. In particular embodiments, the shape of the second metal layer can be formed by bending. In other embodiments, the second metal layer can be provided in a pre-formed shape.

The package design of FIGS. 8-8A may offer a number of advantages over conventional package designs. One advantage is the avoidance of wire bonding during fabrication. Instead, contact between the die and the second metal layer is provided by solder contacts that do not require bending and precise alignment of a metal bond wire. The use of such solder contacts instead of wire bonding reduces the incidence of defects and reduces the overall cost of fabricating the package.

Embodiments of the present invention may also offer advantageous electrical performance. For example, the reduced inductance of metal layers relative to bond wires offers reduced inductance, and may allow faster switching speeds. The use of metal layers in place of narrow bond wires may also advantageously offer a reduced resistance contact to the die housed by the package.

Another possible advantage offered by the embodiment of the package shown in FIGS. 8-8A, is an enhanced ability to dissipate heat. Specifically, the lower metal layer is in thermal communication with the drain contact of the die, and hence is able to conduct heat out of the package through the leads. And, in certain embodiments, a portion of the lower metal layer is exposed on the outside of the package, thereby serving as a heat sink to the surrounding environment.

Moreover, the upper metal layer is also in substantial thermal contact with large areas of the die through the solder connections, and in particular the source pad present on the upper surface of the die. This large area of contact further enhances the flow of heat from the die out of the package to the surrounding environment through the leads. And, in certain embodiments, a portion of the upper metal layer is exposed on the outside of the package, thereby serving as a heat sink to the surrounding environment.

While the specific embodiment of FIGS. 8-8A shows the use of solder balls to establish an electrical connection with only one side of the die, this is not required by the present invention. In accordance with alternative embodiments, solder balls could be employed to establish electrical communication with contacts on both sides of the die.

And while the specific embodiment of FIGS. 8-8A shows the lower metal layer as being in contact with the drain and the upper metal layer as being in contact with the gate/source through solder connections, this is not required by the present invention. Alternative embodiments of the present invention could feature the lower metal layer in contact with the source and gate of the die, with the upper metal layer in contact with the drain. Such an embodiment is illustrated in the simplified cross-sectional view of FIG. 8B. Again, both metal layers would offer the desirable properties of high thermal conductivity and reliable, low cost fabrication.

Moreover, FIG. 8C shows a simplified cross-sectional view of another embodiment of a package in accordance with the present invention. In this particular embodiment, the lower metal layer is bent upward to contact a portion of the upper metal layer, which itself bends downward to extend out of the body of the package. The embodiment of FIG. 8C offers the benefit of ensuring that the upwardly projecting portion of the first metal layer remains securely embedded in the plastic body of the package. In addition, the design of FIG. 8C presents a square or rectangular profile of the heat sink, such that the integral portions of the lower metal layer exposed on the bottom of the package do not extend all the way to the sides of the package.

Following encapsulation of the die within the plastic package body, the package of FIG. 8C can be singulated from the surrounding material by punching through the exposed lead, such that a portion of the lead extends out of the package body and is available for testing. In accordance with alternative embodiments, the package may be singulated from the surrounding material through a sawing process, leaving the exposed leads flush with the surface of the package.

FIG. 8D shows a simplified cross-sectional view of yet another embodiment of a package in accordance with the present invention. In this particular embodiment, the first and second metal layers are configured to project from a half-way point in the thickness of the package. Such a configuration imparts substantial flexibility of use to the package, as it allows the projecting leads to be bent in either direction (up or down), and in a variety of shapes (J-shaped, gull-wing shaped, reverse gull-wing shaped) depending upon the requirements of the environment in which the package is ultimately to be located.

FIG. 8DA shows a simplified cross-sectional view of yet another embodiment of a package in accordance with the present invention. This embodiment shows a reverse-gull wing shaped lead projecting upward toward the heat sink disposed on the top of the package.

FIGS. 8E-8EA show simplified plan and cross-sectional views, respectively, of another embodiment of a package in accordance with the present invention. The package of FIGS. 8E-8EA includes projecting leads located on only one side of the package. A first projecting lead is formed from a portion of the lower metal layer that is positioned at mid-thickness of the package and in contact with a source pad on the die through solder contacts. A second projecting lead is also formed from a portion of the lower metal layer that is in contact with a gate pad on the die through a solder contact. A third projecting lead is formed from a portion of the upper metal layer which is in contact with the drain pad of the die, and which is bent downward before ultimately exiting the package body at the mid-thickness height. As shown in FIG. 8E, the upper metal layer may include an aperture that allows penetration of the plastic encapsulant of the package body, thereby assisting with mechanical interlocking of the upper metal layer within the package.

The embodiments described so far relate to packages housing MOSFET devices having three (gate, source, drain) terminals. However, the present invention is not limited to housing a die of this type. Alternative embodiments of packages in accordance with the present invention can be configured to house die having fewer or more terminals.

For example, FIGS. 8FA-B show plan and cross-sectional views along line 8F-8F′, of a lead frame for a planar two-terminal device (such as a diode) in accordance with an embodiment of the present invention. The lead frame includes a lower metal layer in thermal communication only with a back of the die. The two portions of the upper metal layer are in electrical communication with respective contacts on the upper side of the die.

Similarly, FIGS. 8GA-B show plan and cross-sectional views along line 8G-8G′, of a lead frame for a vertical two-terminal device (such as a diode) in accordance with an embodiment of the present invention. The lead frame includes a lower metal layer in electrical communication with a contact on the back side of the die, and an upper metal layer in electrical communication with a contact on the front side of the die.

FIG. 8H shows a plan view of a lead frame for a package for a dual device, but having three terminals, two of which are connected to the same portion of the device. In particular, the lower metal layer is in electrical communication with a back side contact, and the upper metal layer defines two portions, each in electrical communication with the front-side contact. The particular package shown in FIG. 8H is a TO-220/247/251 type package, featuring a tag hole configured to receive a screw in order to secure the package to a supporting structure. Other embodiments include TO263/252 type package with external leads to the plastic body bent or pre-formed to meet the same plane of the Drain heatsink.

While the embodiments of packages and lead frames just described are designed for a single die, this is not required by the present invention. Alternative embodiments in accordance with the present invention could be configured to house multiple die.

For example, FIGS. 8IA-B show simplified plan and cross-sectional views along line 8I-I′, of an embodiment of a lead frame in accordance with the present invention, which is configured to house two dual die. In this particular embodiment, the two die share the same terminal for a common backside contact, and have separate terminals and contacts on their front sides.

FIG. 8J shows a simplified plan view of an embodiment of a lead frame in accordance with the present invention, which is configured to house two MOSFET die. In this particular embodiment, the two MOSFET die share the same terminal for a common backside contact (drain), and have separate terminals and contacts for the source and gate contacts on the front side of the die.

While the embodiment of FIG. 8J shows a configuration having a single terminal for each of the source, drain, and gate contacts, this is not required by the present invention. FIG. 8K shows a simplified plan view of a lead frame for a MOSFET die having multiple terminals for the source (S) and drain (D).

Similarly, FIGS. 8LA-B show simplified plan and cross-sectional views for a lead frame having multiple source terminals for each of two MOSFET die having drains isolated from each other. The portions of the lead frame in contact with these drains are secured together by a tie-bar structure that is severed (for example by punching) after the molding step. FIG. 8M shows a simplified plan view of a lead frame supporting two die having a common drain contact with two terminals (D1, D2), multiple source terminals for each die.

Similarly, FIG. 8N shows a plan view of another embodiment of a lead frame that features multiple source terminals, and multiple drain terminals with respective clip connections, and which further includes tie-bar connections that are severed from the surrounding metal matrix during singulation and after molding. FIG. 2O shows a simplified plan view of another embodiment of a lead frame housing multiple MOSFET die with pairs of ganged drain terminals to each, and also includes tie-bars.

While the embodiments described so far relate to lead frames and packages configured to house the same type of die, this is also not required by the present invention. Alternative embodiments could be configured to house different die types, for example MOSFETs and integrated circuits (ICs).

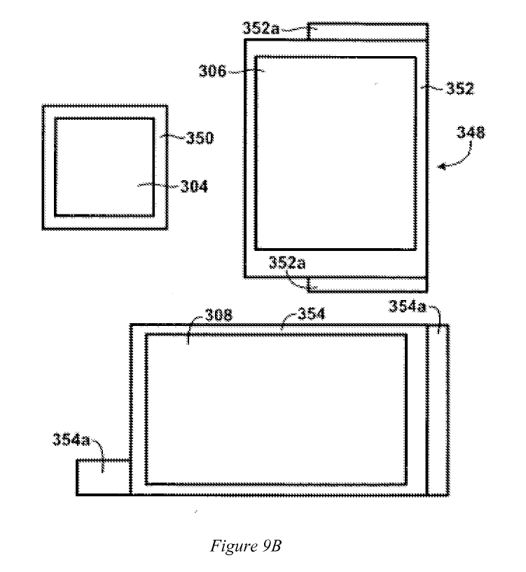

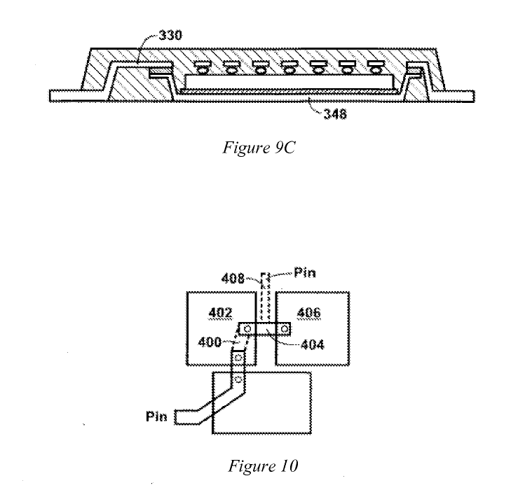

For example, FIGS. 9A-B present plan views of a lead frame 300 in accordance with an alternative embodiment of the present invention. FIG. 9A shows a plan view of the upper metal layer 302 and the three packaged die 304, 306, and 308, while FIG. 9B shows a plan view of the lower metal layer 310 and the packaged die 304, 306, and 308. FIG. 9C shows a simplified cross-sectional view.

The upper metal layer 302 of the lead frame defines the leads in contact with various pads on the upper surface of the housed die. For example, die 304 represents an IC die having many contacts on its upper surface. Accordingly, the upper metal layer 302 of the lead frame comprises a plurality of leads (nos. 5-17) extending over these pads, with intervening solder contacts 312 providing the necessary electrical and thermal communication with the die.

Moreover, the leads of the upper metal layer 302 of the lead frame are not limited to contacting an IC die of a particular size. Thus, as shown in FIG. 9A, these leads include two sets of solder contacts to accommodate IC die occupying larger footprints.

By contrast, die 306 and 308 are MOSFETs having only a gate pad and a larger source pad on each of their top surfaces. Accordingly, the upper metal layer includes only two separate portions for each MOSFET die, which extend over the respective gate/source pads and is in thermal and electrical communication with each through an intervening solder contact(s) 312. Specifically, upper metal portion 330 is in contact with the gate pad of MOSFET die 306 (lead no. 4), and larger upper metal portion 332 is in contact with the source pad of die 306 (lead nos. 33-36).

Although not required, in this particular embodiment the larger upper metal portion 332 comprises a grid-like structure defining a pattern of apertures 333. These apertures reduce the thermal strain in the larger metal portion that results from shrinking and expansion in response to the changing thermal environment inside the package.

While the apertures of the embodiment of FIG. 9A are square-shaped, this is not required by the present invention. Alternative embodiments could feature metal layers defining apertures of other shapes, including but not limited to circular or polygonal, depending upon the particular application.

Similarly, larger portion 340 of the upper metal layer allows thermal and electrical contact with the source pad MOSFET die 308 (lead nos. 21-27). In the particular embodiment of FIGS. 9A-B, the same (wider) portion of the upper metal layer (corresponding to lead no. 17) provides a common contact with both the IC and the gate pad of MOSFET die 308.

The upper metal layer 302 features solitary leads (nos. 18-20 and 32) and ganged leads (nos. 1-3 and 28-31). As described particularly below, leads 1-3, 28-31, and 32 and are in electrical communication with the drain pads on the underside of the MOSFET die, through the lower metal layer.

As indicated in the cross-sectional view of FIG. 9C, prior to emerging from the package body, the extending leads from the upper metal layer of the lead frame 300 are bent downward, so that they ultimately project from the bottom of the thickness of the package. However, this is not required by the present invention. In other embodiments the upper metal layer could emerge at an upper portion of the side of the package, for bending in either direction as described above in connection with FIG. 8D.

The configuration of the lower metal layer 348 shown in FIG. 9B, is simpler than of the upper metal layer. In certain embodiments, portion 350 of the lower metal layer underlying IC die 304, is not in electrical communication with the IC die at all. Accordingly, portion 350 is not in contact with any lead, but is exposed on the bottom of the package to provide a heat sink. In certain embodiments that require the IC to be grounded and connected to a pin, the electrical connect is provided by connecting, in this example, 350 to pin 5 in FIG. 3A.

In particular embodiments requiring connection between two or more die, the connect is provided by having two (or multiple) ball contact locations on an appropriately patterned and continuous pin. Pin 17 in FIG. 9A is such an example, which connects the IC and the Gate of the MOSFET.

Portion 352 of the lower metal layer is in electrical and thermal communication with the drain pad on the underside of MOSFET die 306. Regions 352A jog upward to meet the ganged pins 1-3 and solitary pin 32 of the upper metal layer, thereby providing contact with the drain of MOSFET die 306. These upward jogs in the lower metal layer also serve to provide mechanical interlocking of that layer in the encapsulant of the plastic package body. The underside of lower metal portion 352 is also exposed by the underside of the package to provide a heat sink.

Portion 354 of the lower metal layer is in electrical and thermal communication with the drain pad on the underside of MOSFET die 308. Portions 354a jog upward to meet the ganged pins 28-31 and pin 18 of the upper metal layer, thereby providing contact with the drain of MOSFET die 308. These upward jogs in the lower metal layer also serve to provide mechanical interlocking of that layer in the encapsulant of the plastic package body. The underside of lower metal portion 354 is also exposed by the underside of the package to provide a heat sink.

In the particular embodiment of the package of FIGS. 9A-B, pin no. 18 serves to provide mounting and electrical connection to the heat sink of the drain of the MOSFET 308. Pin nos. 19 and 20 are no connect pins in this embodiment, but can serve as spare locations for thermal and electrical connections in other embodiments.

The embodiment of the lead frame just described, offers certain advantages. One advantage is ready adaptability to house different configurations of die and die sizes. For example, while the MOSFET die are shown occupying the majority of the area available on the grid-like lower metal portions, this is not required. The embodiment of a lead frame shown in FIGS. 9A-B can be configured to house MOSFET die occupying a smaller footprint or a different footprint that fits within the upper metal portion. In certain such embodiments, the location of a particular contact (such as the gate) may be fixed, with the location of other contacts (such as to the source) able to vary in space depending upon the size and shape of the die.

Portions of the metal layers of a lead frame projecting as pin(s) from the body of the package in accordance with embodiments of the present invention, can function internal to the package to perform a signal routing function between two or more separate die mounted on the same horizontal plane according to application needs. For example, FIG. 4 shows a simplified schematic view of an embodiment, wherein IC die 401 and MOSFET die 402 are connected through a continuous pin with solder ball connections. Furthermore, FIG. 4 shows according to certain embodiments, this continuous pin connection can be extended as portion 400 and then to portion 404, which provides continuous signal routing between contacts on the IC die 402 and MOSFET die 406. In certain embodiments, the portion 404 extends as projected pin portion 408.

While the embodiments shown so far depict a package and lead frame configured to house multiple die located with signal routing in the same horizontal plane, this is not required by the present invention. Alternative embodiments of packages and lead frames in accordance with the present invention may feature multiple die oriented in a vertical stack or other orientations.

For example, FIG. 11 shows a simplified cross-sectional view of an embodiment of a package configured to house two flip-chip die. The first flip-chip die 500 is supported on the underside of an upper metal layer 502 of the lead frame. The second flip-chip die 504 is supported on a lower metal layer 506 of the lead frame. Contacts on the surfaces of die 500 and 504 are in electrical communication with each other through solder balls 508. Other contacts on the surface of the first die 500 are in electrical contact with a middle metal layer 510.

Apart from the stacked die configuration, a couple of aspects of the embodiment of FIG. 11 are worthy of note. First, the package of FIG. 11 has exposed heat sinks on both of its sides. One such heat sink could be in thermal communication with the underlying PC board, with the other heat sink in thermal communication with the surrounding environment. It is to be understood that such use of multiple heat sinks is also possible for one or more of the embodiments previously described.

Second, embodiments in accordance with the present invention are not limited to the use of two or any number of multiple metal layers, or to incorporating only two die. Rather, embodiments of the present invention can utilize multiple metal layers sandwiching any number of desired die.

As described above in connection with FIGS. 9A-C, lead frames according to embodiments of the present invention offer flexibility to package designers, by allowing die of multiple sizes to be supported on the various metal layers. Further flexibility in package design may be achieved by combining multiple modules in a sandwiched configuration according to embodiments of the present invention.

For example, FIG. 12 shows package 600 of FIG. 12 including a first flip-chip die 602 sandwiched between first and second metal layers 604, 606 as shown. Fabrication of a multi-chip module (MCM) is completed by incorporating a module 609 comprising a second flip-chip die 610 that is itself sandwiched between metal layers 612 and 614. Allowing the package to be assembled from a plurality of sandwiched die components, in a manner analogous to the interlocking pieces of a pul6le, imparts substantial additional flexibility in the design of a package for particular needs.

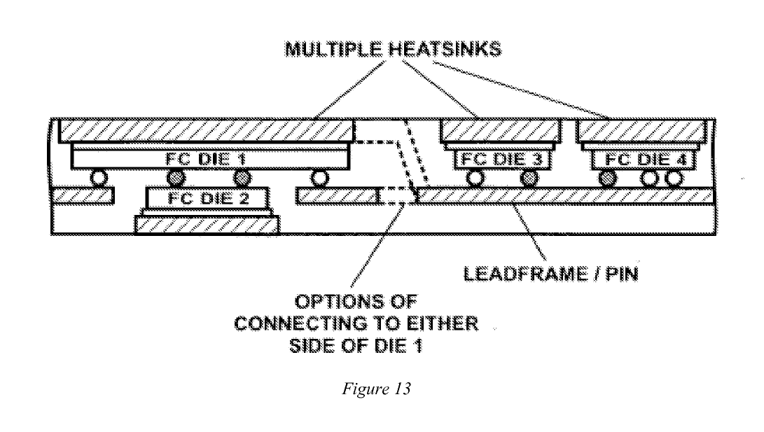

FIG. 13 shows a simplified cross-sectional view of still another embodiment of a package in accordance with the present invention, that is formed from a plurality of smaller elements. In particular, the package comprises die having interconnects and signal routing in the same plane through a solder ball contact with one of the metal layers of the sandwich (e.g. through the shaded solder balls and the lower metal layer between FC DIE 3 and FC DIE 4). The package also includes die having vertical interconnections and signal routing with each other through solder ball contacts (e.g. through the shaded solder balls and between FC DIE 1 and FC DIE 2). In this package, the lower metal layer of the sandwich could remain in the lower plane to establish contact with the lower metal layer supporting one of the vertically connected die, or could be bent upward to establish contact with the upper metal layer in contact with the upper of the vertically connected die. The package of FIG. 13 includes heat sinks on both sides, with the top side having multiple heat sinks.

Embodiments in accordance with the present invention are not limited to housing particular types of die. However, certain types of die such as power devices are particularly suited for packaging according the present invention. For purposes of the instant application, the term “power device” is understood to refer to semiconductor devices used as switches or rectifiers in power electronic circuits. These include but are not limited to discrete devices such as diodes, power MOSFETs, insulated gate bipolar transistors (IGBTs), and Power Integrated Circuits used in the analog or digital control of the discrete devices.

In combination, the power devices are commonly employed to provide power management functions such as power supply, battery charging control systems. Power discrete devices having a planar or vertical structure, can handle power from a few milliwatts to tens of kilowatts. For the packages described above, a typical power device may operate at between about 500 W and 5 mW. In the off state, reverse breakdown can occur at voltages from about a few volts up to about 2000 volts. The operating current for power devices can range from a few milli-Amperes, to several hundred Amperes.

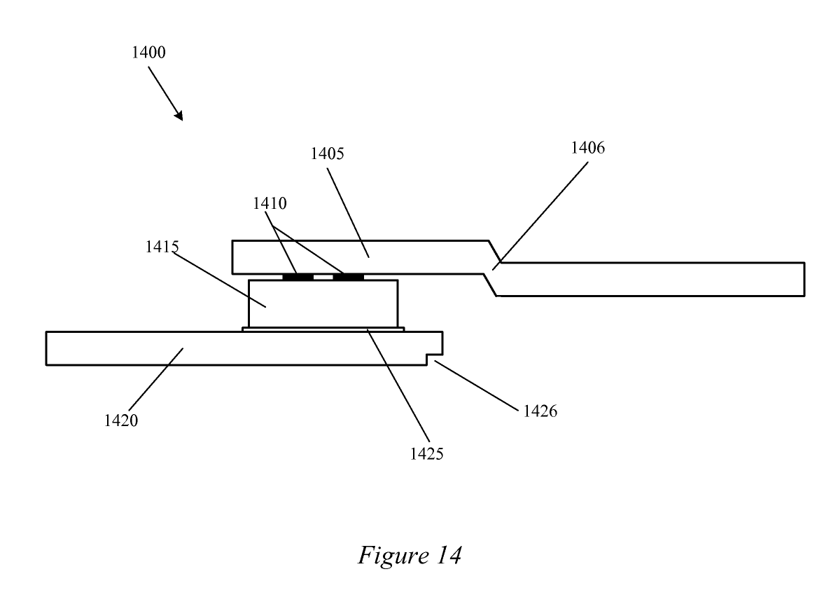

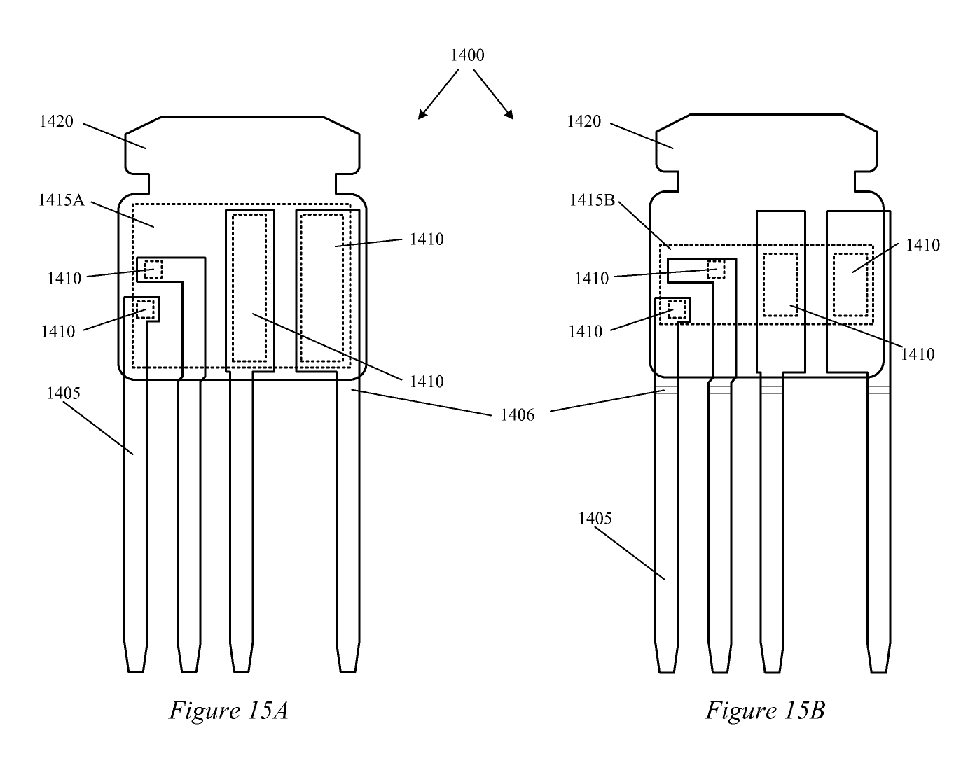

FIG. 14 is side view of device 1400 with a two component lead frame according to embodiments of the invention. The two component lead frame includes the leads 1405 and the heat sink 1420. The leads 1405 can be part of a finger frame and/or can include stamped features such as feature 1406 and the shapes shown in FIGS. 15A and 15B. The leads 1405 do not include clip connectors or plate connectors between portions of the leads. Instead, each lead is a unitary structure without clip and/or plate connectors.

The leads 1405 are coupled with the die 1415 through the diepad 1410. The diepad 1410 can include any features, characteristics, or proprieties discussed throughout this disclosure in regard to other diepads (e.g., diepad 204). Moreover, the connection between the die 1415, the die pad 1410, and/or the leads 1405 can be made using any techniques know in the art. For example, connection to the die pad 1410 can include a connecting layer that may, for example, include a plurality of solder balls, solderable bumps, and/or solderable pillars. The heat sink 1420 can be coupled with the die 1415 using any number of techniques. For example, the heat sink 1420 can be coupled with the die 1415 using thermally conductive glue and/or solder 1425.

The components of device 1400 can have dimensions that vary. For example, the leads 1405 can vary in length. Also, the die 1415, the diepad 1410, and/or the heat sink 1420 can include widths.

Heat sink 1420 can comprise a complex shape. This complex shape, for example, can include one or more notches, like notch 1426. The complex shape of and/or notches in heat sink 1420 can provide added features for plastic encapsulation to provide traction for the encapsulant. Encapsulation can be a plastic material that encapsulates the die, diepad, all or a portion of the leads, and all or a portion of the heat sink.

FIGS. 15A and 15B show a top view of device 1400 with a two component lead frame according to embodiments of the invention. As shown the leads 1405 include various shapes and configurations. These different shapes can allow the leads 1405 to be connected with dies having different sizes. The die 1410A shown in FIG. 15A is larger than the die 1410B shown in FIG. 15B. Despite the size difference, the leads 1405 have the same size, shape, configuration, and/or dimension. The different lead shapes shown in the figure can be formed by stamping. Moreover, leads may be crimped or stamped to create three-dimensional features. For example, each lead can be crimped at point 1406.

The leads 1405 can have a first portion that is coupled with the die 1415 and a second portion that extend beyond the body of the die 1415. The portions of the leads 1405 that extend beyond the body of the die 1415 can be substantially parallel with one another. For example, these leads are parallel within standard manufacturing tolerances.

Moreover, leads 1405 do not require clips or plate connections. Instead, each lead is an unitary structure that extends from the die 1415 to the portion of the lead that connects with external circuitry. No additional fingers or leads are connected with leads 1405.

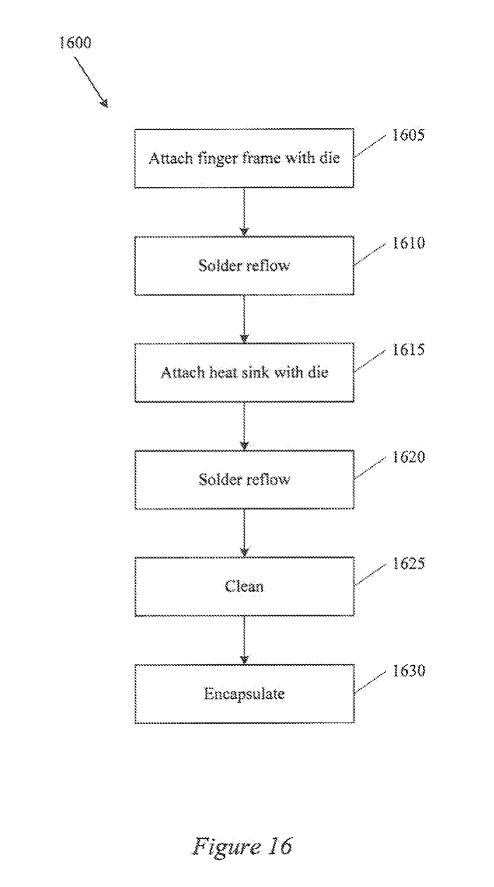

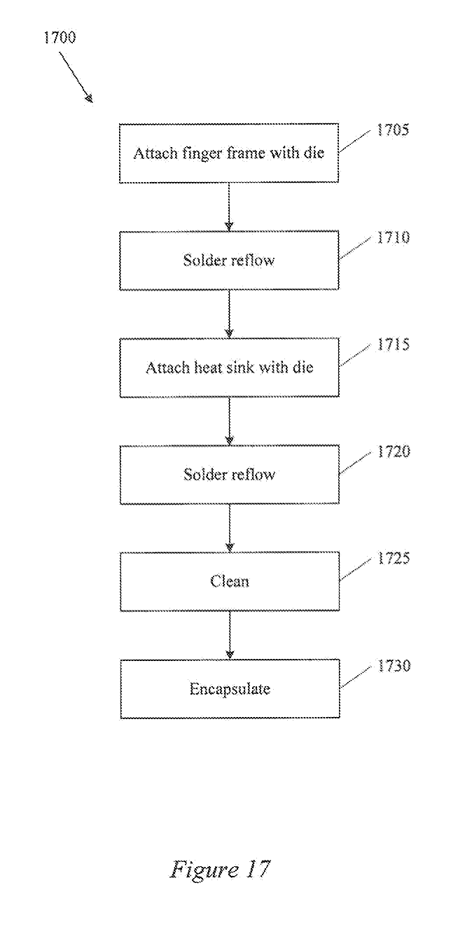

FIG. 16 is a flowchart of process 1600 for forming a two component lead frame according to some embodiments of the invention. At block 1605 a finger frame is attached with the die. The finger frame can include a plurality of leads (or fingers). The finger frame can include leads that are coupled together, which may be decoupled or cut later in the process. At block 1610 the finger frame is soldered with the die and/or the die pad using a solder reflow process.

At block 1615 the heat sink can be attached with the die. The heat sink can be attached to the opposite side of the die as the finger frame or leads as shown in FIG. 14. The heat sink can then be soldered with the die at block 1620 using a solder reflow process. The solder connection can provide for good thermal transfer between heat sink and die. Various other connection processes can be used. At block 1625 the device can be cleaned, and at block 1630 the device can be encapsulated with in a plastic. These two blocks can occur using any type of cleaning and or encapsulate processes.

While the above is a full description of the specific embodiments, various modifications, alternative constructions and equivalents may be used. Therefore, the above description and illustrations should not be taken as limiting the scope of the present invention which is defined by the appended claims.

What is claimed is:

1. A semiconductor device package comprising:
a plurality of leads, wherein each lead comprises a first portion and a second portion, wherein the first portion and the second portion of each lead comprise a unitary structure;
a die;
a diepad disposed between the die and the first portion of the plurality of leads, wherein the diepad electrically couples a different portion of the die with a different one of the plurality of leads;
a heat sink coupled with the die;
wherein the second portion of the plurality of leads extend from the diepad and are substantially parallel with each other.

2. The semiconductor device package according to claim 1, wherein the heat sink comprises one or more notches.

3. The semiconductor device package according to claim 1, wherein the heat sink comprises complex cross-sectional profile.

4. The semiconductor device package according to claim 1, wherein diepad comprises a solder connecting layer.

5. The semiconductor device package according to claim 1, further comprising a plastic package body encapsulating the die, the diepad, at least a portion of the plurality of leads, and at least a portion of the plurality of leads.

6. The semiconductor device package according to claim 5, wherein the heat sink comprises complex cross-sectional profile that mechanically interlocks the heat sink within the plastic package body.

7. The semiconductor device package according to claim 1, wherein the leads do not include a clipping mechanism.

8. A semiconductor device package comprising:
a lead frame consisting of:
a plurality of leads having a stamped feature, a first portion, and a second portion; and
a heat sink;
a die;
a diepad disposed between the die and the first portion of each of the plurality of leads, wherein the diepad electrically couples a different portion of the die with a different one of the plurality of leads.

9. The semiconductor device package according to claim 8, further comprising a plastic package body encapsulating the die, the diepad, and at least a portion of the plurality of leads.

10. The semiconductor device package according to claim 8, further comprising a plastic package body encapsulating the die, the diepad, at least a portion of the first portion of the plurality of leads.

11. The semiconductor device package according to claim 8, wherein the second portion of each of the plurality of leads are substantially parallel with each other.

12. The semiconductor device package according to claim 8, wherein a stamped feature differentiates the first portion of the leads from the second portion of the leads.

13. The semiconductor device package according to claim 8, wherein the heat sink comprises complex cross-sectional profile.

14. The semiconductor device package according to claim 8, wherein the plurality of leads do not include a clip feature.

15. The semiconductor device package according to claim 8, wherein the second portion of the leads extend away from the die.

16. The semiconductor device package according to claim 8, wherein the first portion of the plurality of leads comprise complex shapes.

17. The semiconductor device package according to claim 8, wherein at least one lead of the plurality of leads includes a first portion with a shape distinct from the first portion of the other leads.

18. A semiconductor device package comprising:
a die;
a diepad electrically coupled with different portions of the die;
a plurality of leads electrically coupled with diepad connecting each lead with a different portion of the die, wherein each lead includes a portion that extends beyond the body of the die, and each lead does not include clipping mechanisms;
a heat sink coupled with the die.

19. The semiconductor device package according to claim 18, wherein the portions of each lead that extends beyond the body of the die are parallel with each other.

20. The semiconductor device package according to claim 18, further comprising a plastic package body encapsulating the die, the diepad, and at least a portion of the plurality of leads.

21. The semiconductor device package according to claim 18, wherein each of the plurality of leads include a stamped feature.
